(19) United States
(12) Patent Application Publication
(10) Pub. No.: US 2002/0080052 A1
(43) Pub. Date: Jun. 27, 2002

(54) Transformation of data

(76) Inventor: Jean Gobert, Maisons Alfort (FR)

Correspondence Address: U.S. Philips Corporation, 580 White Plains Road, Tarrytown, NY, 10591, US

(21) Appl. No.: 09/961,971

(22) Filed: Sep. 24, 2001

(30) Foreign Application Priority Data
Sep. 27, 2000 (EP) 00402674.6

(51) Int. Cl. H03M 7/46

(52) U.S. Cl. 341/63

(57) ABSTRACT

During the transformation of data, for example the decoding of encoded and transformed data, there is front-end processing (FE) to generate a data block for subsequent back-end processing (TR), this front-end processing may include run-length decoding (RLD). Auxiliary data (AUX) indicating the structure of the data block (MB) is also generated during the front-end processing. Typically, the auxiliary data is indicative of the location of zero coefficients within the data block. The implementation of the back-end processing (TR) is adapted to the structure of the data block (MB) based upon the content of the auxiliary data (AUX), thereby making the implementation more efficient. For example, the content of the auxiliary data can determine which shortcuts can be applied during the implementation of an inverse discrete cosine transformation. Generation of the auxiliary data during the front-end processing (FE) is less onerous than investigating the structure of the data block just prior to inverse transformation, because the former involves taking action only for non-zero coefficients, whereas the latter involves checking all coefficients in the block.

The present invention relates to the transformation of data during front-end and back-end processing, typically during the decoding of encoded and transformed data, such as run-length encoded DCT data. The encoded and transformed data may be, for example, video information which has been encoded in accordance with a Moving Pictures Expert Group (MPEG) standard.

In order to reduce the number of bits needed to represent a given data stream, data compression techniques often process the data stream using the discrete cosine transformation (DCT) followed by run-length encoding of the resulting coefficient values. The run length encoding process converts into a code-word each sequence of zeroes followed by a non-zero coefficient, the run-length of the sequence together with the coefficient value can be termed a “run-value pair”. U.S. Pat. No. 4,901,075 describes an encoding method and apparatus of this type. At the decoder, reconstitution of the original data will involve decoding of the run-length encoded data and application of an inverse discrete cosine transformation (IDCT). WO99/35749 describes a method and device suitable for receiving and decoding run-length encoded data. A variety of methods are known for applying an IDCT.

In the encoding process, there will generally be additional intervening steps, for example, quantization of the DCT coefficients, prediction removal of certain of the quantized coefficient values before run-length encoding, and the run-length encoding commonly makes use of one or more variable-length codes to represent the run-length encoded entities. There may also be additional steps preceding the DCT, for example, to allow motion compensation. The document ISO/IEC 13818-2 describes additional processes of these types involved in the encoding of video and associated audio information. Corresponding inverse processes will be involved during decoding. However, the present invention is not concerned with the details of these additional processes.

Here, the expression “front-end processing” will be used to designate all the decoding steps involved in generating coefficients that are subsequently subjected to backend processing, for example processing including an IDCT.

Video compression techniques, such as those used in encoding data according to an MPEG standard, commonly apply the DCT to two-dimensional blocks of pixels, thus requiring application of a two-dimensional IDCT at the decoder. This is one of the most time-consuming tasks that the decoder must perform. The two-dimensional IDCT is generally implemented by performing a series of one-dimensional IDCT processes. For example, an IDCT applied to an 8×8 block of pixels can be achieved in two passes: the first pass involves applying a one-dimensional IDCT to each row of 8 points within the block (i.e. 8 horizontal, one-dimensional IDCTs in total), and storing the resultant 8 rows of data in an intermediate result block, the second pass involves applying a one-dimensional IDCT to each column of 8 points within the intermediate result block (i.e. 8 vertical, one-dimensional IDCTs in total) and storing the resultant 8 columns of data in a final result block. The order of performing the vertical and horizontal IDCTs can be switched without affecting the results.

Now, a one-dimensional IDCT can be simplified if some of the inputs thereto are null (i.e. take zero values). Such a simplified implementation of an IDCT is termed a “shortcut”. For example, if all of the inputs to a one-dimensional IDCT are null then the outputs are all zeroes. Thus, in such a case, it is unnecessary to actually perform the IDCT, it is sufficient to detect the “all-zero” configuration of the input and write all zeroes into the output. This short-cut can be designated “IDCT0”. Similarly, if only the first input to a one-dimensional IDCT is non-zero, with the remainder all being null, then all outputs are equal to a scaled value of the non-zero input. The corresponding shortcut can be designated “IDCT1”. In general, we can designate as “IDCTn” a shortcut usable when all but the first n coefficients input to the one-dimensional IDCT are zero.

In many applications, the majority of the IDCT inputs take null values. Typically, in video compression systems, a block of 64 inputs to the IDCT process in the decoder contains only 5 to 10 non-zero values. It has therefore been proposed to use shortcuts to speed up the implementation of IDCTs in video decoders. However, the time saving achieved by using the shortcuts is eroded because of the need to detect the “structure” or “configuration” (number and position of non-zero values) of the data input to the IDCTs.

It is an object of the present invention to enable the implementation of transformations, involving front-end and back-end processing of data, to be rendered more efficient via knowledge of the structure of the data to be subjected to the back-end processing, whilst avoiding the usual overhead involved in detection of the configuration of the input data.

The invention takes the following aspects into consideration. In the front-end processing involved in transforming the data, information becomes available as to the positioning, within the data stream, of minority coefficients (typically, non-zero coefficients) and/or majority coefficients. Thus, during this front-end processing, it is possible to generate auxiliary data indicating the positioning of these minority and/or majority coefficients and to supply this auxiliary data, along with the primary data, to the processing device implementing the back-end processing. This processing device can thus, based on the content of the auxiliary data, adapt the way in which the back-end processing is implemented, to the structure of the data.

For example, in the case where the back-end processing includes an inverse transformation such as an IDCT, and the front-end processing involves a run-length decoding process generating data indicating the length of runs of zero coefficients (majority coefficients) and the value of the non-zero coefficients (minority coefficients), the auxiliary data enables it to be determined which shortcuts, if any, can be applied so as to speed up implementation of the IDCT.

The invention and additional features, which may be optionally used to implement the invention to advantage, are apparent from and elucidated with reference to the drawings described hereinafter.

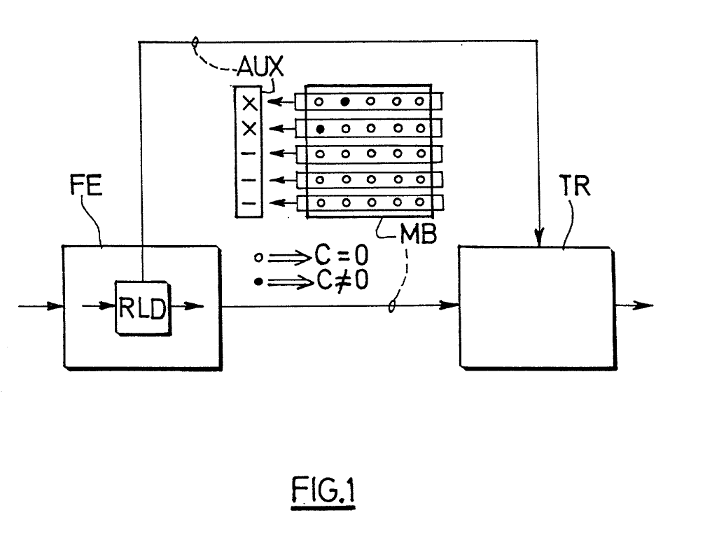

FIG. 1 is a block diagram showing the main components of a decoder implementing a method embodying the present invention;

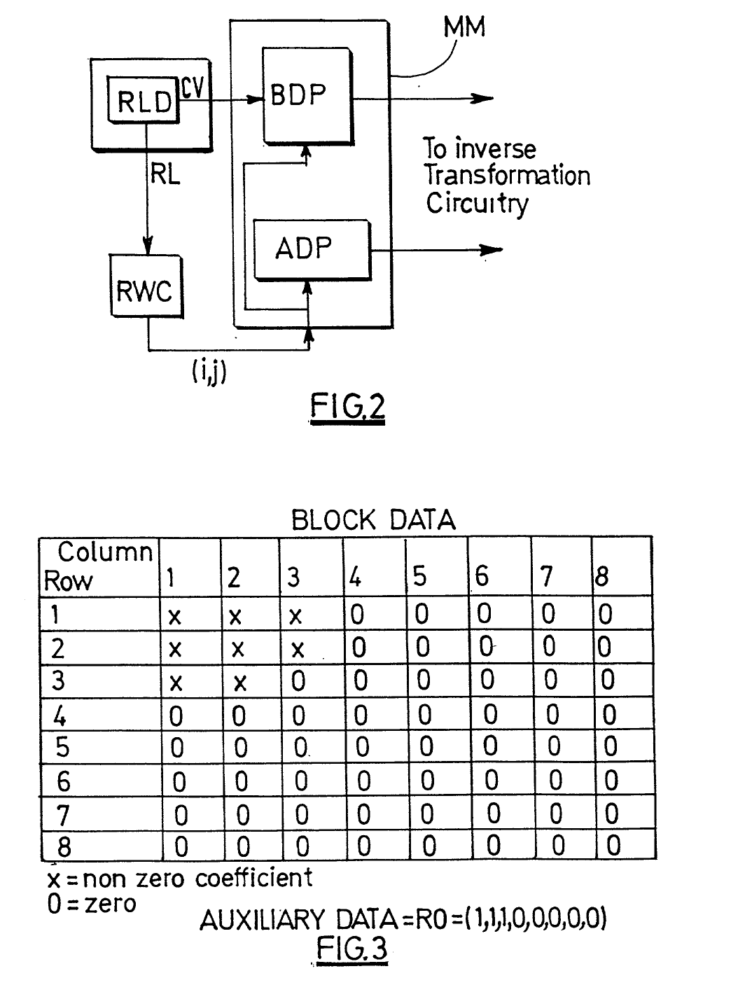

FIG. 2 is a block diagram illustrating circuitry for generating data block and auxiliary data according to an embodiment of the present invention; and

FIG. 3 shows an example of a data block and associated auxiliary data according to one embodiment of the present invention.

First some remarks will be made on the use of reference signs. Similar entities are denoted by an identical letter code throughout the drawings. Various similar entities may be shown in a single drawing. In that case, a numeral is added to the letter code so as to distinguish similar entities from each other. The numeral will be between parentheses if the number of similar entities is a running parameter. In the description and claims, any numeral in a reference sign may be omitted if appropriate.

FIG. 1 illustrates a decoder using the general principle of the present invention to improve efficiency of an IDCT. A transformation circuit, TR, implements an inverse discrete cosine transformation on successive blocks, MB, of two-dimensional data. Each data item in a block, MB, is a coefficient, C, that can take a zero or non-zero value. The data blocks, MB, are generated by front-end processing circuitry, FE, including a device, RLD, implementing a run length decoding process.

Each run-value pair decoded by the device RLD includes data (RL=run length) on the number of zeroes in the run and data (CV=coefficient value) on the value of the following (or, in some cases, preceding) non-zero coefficient. The positioning of the decoded non-zero coefficients within the two-dimensional blocks MB output from the front-end processing depends upon the encoding scheme that was used. In MPEG encoding techniques, a zig-zag scanning approach is generally used to convert between two-dimensional DCT data and the serial data to be run-length encoded. A matching process is used in the decoder to convert between the run-length decoded data and two-dimensional data blocks. However, other approaches are possible. Whichever approach is used, this will be known in the decoder device. Accordingly, in the decoder's front-end processing device, FE, it is possible to generate, for each block MB, auxiliary data indicating the positioning of non-zero coefficients within the block. The transformation circuit, TR, can use this auxiliary information so as to adapt the implementation of the IDCT process, to the structure of the block data.

For example, as represented in FIG. 1, the auxiliary data may indicate the location, within the block, of rows that contain only zero coefficients (the bottom three rows in the illustrated block). In this example, since the one-dimensional IDCT of a sequence of zeroes produces a sequence of zeroes, when the transformation circuit, TR, implements the two-dimensional IDCT of this 5×5 block MB, via successive series of horizontal (one-dimensional) IDCTs and vertical (one-dimensional) IDCTs, it can skip the horizontal transformations of the bottom three rows of the block illustrated in FIG. 1. Moreover, if the transformation circuitry works “in place”, in other words, overwrites its intermediary and final results into the same memory locations as were used for the input block, then the data of the “skipped rows” is simply left in place in memory. Thus, the auxiliary data enables the IDCT to be implemented efficiently without any need for the transformation circuitry to investigate the structure of the block data.

The generation of the auxiliary data by the front-end processing circuitry is not costly in terms of time or circuitry because the front-end processing circuitry is required to take action only in relation to non-zero coefficients, and there is a relatively small number of these for each data block. By way of contrast, in conventional techniques, where the structure of the data block is investigated by the transformation circuitry, all values must be examined to see whether they take zero or non-zero values.

There will now be described in greater detail, with reference to FIGS. 2 and 3, and by way of non-limiting example, a method and apparatus for generating and using auxiliary data indicative of the location in a data block of rows (or columns) containing only zero coefficients.

FIG. 2 illustrates one example of circuitry for generating the block and auxiliary data fed to the transformation circuitry, TR, in the decoder. In this example, the output from the run-length decoder, RLD, is supplied to a memory, MM, and to a read/write controller, RWC, that controls the addresses at which data is written into the memory. The memory, MM, includes respective portions (BDP, ADP) for storing block data and auxiliary data. Once a whole block of data has been decoded, the read/write controller also emits a read trigger signal to trigger the supply to the transformation circuitry, TR (not shown in FIG. 2) of the contents of the block data and auxiliary data portions of memory MM.

When decoding of a block is about to begin, the contents of the block data and auxiliary data portions of the memory MM are reset to zero. The run-length decoder, RLD, decodes each code-word to generate a run-length pair (RL,CV). The coefficient value, CV, is written into the block data portion BDP of a memory MM, whereas the run-length, RL, is supplied to the read/write controller, RWC. The read/write controller RWC generates address information (i,j) indicating the row (i) and column (j) location of the non-zero coefficient, CV, within the associated block of data, based on predetermined information (for example, inverse zig-zag scanning information). The coefficient value is written into the block data portion BDP of the memory MM at a corresponding address.

The address information generated by the read/write controller, RWC, is also used to generate auxiliary information indicating the rows of this block that contain non-zero coefficients. FIG. 3 shows an example of the structure of one block of data and the auxiliary data that can be used to indicate this structure.

In general, each block of data can have r rows and c columns. In the example illustrated in FIG. 3, the blocks of data have 8 rows and 8 columns and the represented block has non-zero coefficients only in the first three rows. Here, the auxiliary information takes the form of a row vector R0, the bit i of this vector takes value 0 only if all coefficients in row i of the data block take value 0. Otherwise, if there are any non-zero coefficients in row i of the data block, then bit i of vector R0 takes value 1.

Vector R0 can be produced very simply based on the address data generated by the read/write controller RWC. During decoding of a given block if, for the associated run-length pairs, the read/write controller, RWC, generates address signals including row values i=1, 2 and 3, indicating non-zero coefficients in the first three rows of the data block, then bits 1, 2 and 3 of the auxiliary data vector R0 stored in the auxiliary data portion of memory MM will be set at value 1, all other bits of row vector R0 will remain set at zero.

When the transformation circuitry, TR, receives the block data and associated auxiliary data (here, row vector R0) as shown in FIG. 3, inspection of the auxiliary data shows that, if the two-dimensional IDCT is implemented by successive sets of horizontal and vertical one-dimensional IDCTs, horizontal IDCTs can be skipped for the bottom five rows of the data block. Moreover, it is known from the auxiliary data (R0) that only the first three bits of each column may contain non-zero values. Thus, when the eight, vertical IDCTs are implemented, eight shortcuts IDCT3 can be applied. Thus the transformation circuitry, TR, can adapt the implementation of the IDCT to the structure of the data block without itself having to analyze what is that structure.

The above-explained example described the case where the auxiliary data consisted solely of a row vector, R0, indicating the location in a data block of rows containing all zeroes. It is to be understood that the auxiliary data can take other forms. For example, a corresponding column vector C0 could be generated instead of, or additionally to, the row vector R0. The bit j of the column vector C0 would take value 0 only if all coefficients in column j of the data block are zeroes, otherwise it would take value 1.

Also, further row vectors Rn can be defined, with n taking values from 1 to c-1: the i^{th} bit of row vector Rn indicates whether or not the last c-n coefficients of row i all take the value zero. More particularly, bit i of row vector Rn will take value 0 only if the last c-n coefficients of row i are all zeroes. Additionally or alternatively, further column vectors Cm can be defined, with m taking values from 1 to r-1. The j^{th} bit of row vector Cm indicates whether or not the last r-m coefficients of column j take the value zero. More particularly, bit j of column vector Cm will take value 0 only if the last r-m coefficients of column j are all zeroes.

For a two-dimensional data block having r rows and c columns, a full set of row and column vectors can be generated by the method set out below. However, it is to be understood that it is not mandatory to generate the full set of vectors, R0, R1, . . . , Rc-1, C0, C1, . . . , Cr-1; the set of generated vectors could be restricted, as desired, for example to the set R0, R1, C0, C1.

For a block having r rows and c columns, the vectors are first reset so as to contain all zeroes. In other words:

for all u, 0≦u≦c-1, all bits of Ru=0

for all v, 0≦v≦r-1, all bits of Cv=0

Next, during the front-end processing, for each non-null coefficient that is retrieved, located at row i and column j of the data block, the vector values are updated, as follows;

for all u, 0≦u≦j, set bit i of Ru=1

for all v, 0≦v≦i, set bit j of Cv=1

As indicated above, shortcuts IDCTn (IDCTm) for implementation of one-dimensional IDCTs exist enabling implementation of the IDCT to be simplified in the case where the last c-n (or r-m) coefficients of a row (or column) are all zeroes. Accordingly, by including the above-mentioned further row vectors (and/or column vectors) in the auxiliary data, the transformation circuitry can determine from inspection of the auxiliary data whether any of these other shortcuts, IDCTn, can be used for efficient implementation of the IDCT.

In the case where the auxiliary data includes several row vectors, R0, R1, etc., the transformation circuitry need not inspect all bits of all row vectors. First, all bits of the row vector R0 are inspected. This determines which rows can be skipped altogether (the bits corresponding to rows that can be skipped can be considered to have “passed” the test on R0). Next, in row vector R1, the transformation circuitry inspects only those bits that correspond to “non-skipped” rows, that is, only those bits that failed the test on R0. This determines which rows can be processed using shortcut IDCT1. In general, in row vector Rn, the transformation circuitry inspects only those bits that have not yet “passed” a test on an earlier-inspected row vector; this determines which rows can be processed using shortcut IDCTn. Once all bits (rows) have passed a test, the transformation circuitry can stop investigation of the row vectors.

The corresponding is true when the auxiliary data includes several column vectors, C0, C1, etc.

In some cases, the location of non-zero coefficients in the data block may mean that implementation of the first pass of the IDCT in a particular direction (horizontal or vertical) would result in use of a greater overall number of shortcuts and, thus, a more efficient overall transformation. Therefore, in a case where the auxiliary data includes information indicating the location of non-zero coefficients both in the rows and in the columns of the data block, it is advantageous if the transformation circuitry is adapted to compare this auxiliary row and column data so as to choose the direction for the first pass of the IDCT.

Thus, a detector detects whether the matrix of frequency coefficients contains more zero rows than zero columns, or whether it contains more zero columns than zero rows. If there are more zero rows than zero columns, the first step is a one-dimensional transformation of the rows. If there are more zero columns than zero rows, the first step is a one-dimensional transformation of the columns. Accordingly, it is possible to make optimal use of the presence of zero rows or zero columns for each matrix to be transformed in terms of saving calculations. This reduces power consumption and allows the transformation to be carried out with slower and thus cheaper electronic elements.

The drawings and their description hereinbefore illustrate rather than limit the invention. It will be evident that there are numerous alternatives that fall within the scope of the appended claims. In this respect the following closing remarks are made.

Although the above-described specific embodiments concern the case where the run-length decoding process generates run-value pairs relating to runs of zeroes and the values of non-zero coefficients, the present invention is not limited to this case. On the contrary, it can also be applied in the case where the data includes runs of coefficients taking some other value (these coefficients being termed “majority coefficients”) followed (or succeeded) by coefficients taking some further values (termed “minority coefficients”). The auxiliary data will generally then be indicative of the location within a data block of the minority coefficients, and the inverse transformation can be rendered more efficient by knowledge of the location of these minority coefficients.

In other words, although the above-described embodiments relate to the efficient implementation of an IDCT, the invention is applicable also to other inverse transformations whose implementation can be rendered more efficient via knowledge of the structure of the data (in terms of majority and minority coefficients).

Similarly, the data processed in the front-end processing need not be run-length coded data. The present invention is applicable also if this data represents the distribution of majority and/or minority coefficients in some other way (for example the initial data may indicate the position of minority coefficients in terms of co-ordinates of the coefficient within a data block).

Further, the above description concentrates on inverse transformations of two-dimensional data blocks. However, the invention is also applicable to one-dimensional data blocks, or multi-dimensional data blocks in general.

Also, the encoded and transformed data can be differential data, that is, data indicating the difference between some primary data and, for example, a predicted value.

The data processing arrangement mentioned in the appended claims may be, but is not limited to, an MPEG 2 decoder.

Any reference sign in a claim should not be construed as limiting the claim.

1. A method of data processing, comprising:
a front-end processing step in which input data is processed so as to obtain a block of data comprising a set of coefficients,
a back-end processing step in which the block of data is processed;
characterized in that:
the front-end processing step generates auxiliary data while processing the input data, the auxiliary data being indicative of the location, within the data block, of coefficients that take a majority value and/or of coefficients that take a minority value; and
the implementation of the back-end processing step is adapted on the basis of the auxiliary data.

2. The method of claim 1, wherein the back-end processing step comprises an inverse discrete cosine transformation (IDCT).

3. The method of claim 1 or 2, wherein the front-end processing step includes a run-length decoding process.

4. The method of claim 1, 2 or 3, wherein the received block of data is a multidimensional block of data, and the auxiliary data comprises data indicative of the location, with reference to a sub-space of the block of data, of coefficients taking a majority value and/or coefficients taking a minority value.

5. The method of claim 4, wherein the auxiliary data comprises data indicative of the location, with reference to one dimension of the block of data, of coefficients taking a majority value and/or coefficients taking a minority value.

6. The method of claim 5, wherein the auxiliary data comprises data indicative of the location, with reference to rows in the block of data, of coefficients taking a majority value and/or coefficients taking a minority value.

7. The method of claim 5 or 6, wherein the auxiliary data comprises data indicative of the location, with reference to columns in the block of data, of coefficients taking a majority value and/or coefficients taking a minority value.

8. The method of any previous claim, wherein the back-end processing includes a separable transformation comprising first and second passes in respective different directions, and there is provided the step of selecting the direction for implementation of the first pass of the separable transformation, based upon the auxiliary data.

9. The method of any previous claim, wherein the auxiliary data comprises data indicative of the location, within the block of data, of zero coefficients.

10. The method of any previous claim, wherein the received block of data is a two-dimensional block of data having r rows and c columns, where r and c are integers, the auxiliary data comprises data indicative of which rows contain only zero coefficients, the back-end processing comprises a two-dimensional IDCT and is adapted to implement horizontal IDCTs so as to skip transformation of rows identified, by the auxiliary information, as containing only zero coefficients.

11. The method of claim 10 wherein, in the case where the auxiliary information indicates that the last r-n of the rows contain only zero coefficients, the adaptation step further comprises implementing vertical IDCTs by applying a simplified IDCT algorithm (IDCTn), the simplified IDCT algorithm being determined by n.

12. The method of any one of claims 1 to 9, wherein the received block of data is a two-dimensional block of data having r rows and c columns, where r and c are integers, the auxiliary data comprises data indicative of which columns contain only zero coefficients, the back-end processing comprises a two-dimensional IDCT and is adapted to implement vertical IDCTs so as to skip transformation of columns identified, by the auxiliary information, as containing only zero coefficients.

13. The method of claim 12 wherein, in the case where the auxiliary information indicates that the last c-m of the columns contain only zero coefficients, the adaptation step further comprises implementing horizontal IDCTs by applying a simplified IDCT algorithm (IDCTm), the simplified IDCT algorithm being determined by m.

14. A data processing arrangement comprising:
a front-end processor adapted to process input data so as to obtain a block of data comprising a set of coefficients; and
a back-end processor adapted to process the block of data;
characterized in that:
the front-end processor is arranged to generate auxiliary data while processing the input data, the auxiliary data being indicative of the location, within the data block, of coefficients that take a majority value and/or of coefficients that take a minority value; and
the back-end processor is arranged to adapt the processing of the block of data, on the basis of the auxiliary data.

15. A computer program product for a data processing arrangement comprising:
a front-end processor adapted to process input data so as to obtain a block of data comprising a set of coefficients; and
a back-end processor adapted to process the block of data; the computer program product comprising a set of instructions which, when loaded into the data processing arrangement, causes:
the front-end processor to generate auxiliary data while processing the input data, the auxiliary data being indicative of the location, within the data block, of coefficients that take a majority value and/or of coefficients that take a minority value; and
the back-end processor to adapt the processing of the block of data, on the basis of the auxiliary data.
